(19) United States
(12) Patent Application Publication
(10) Pub. No.: US 2023/0268332 A1
(43) Pub. Date: Aug. 24, 2023

(54) POWER MODULE PACKAGE AND METHOD OF FORMING THE SAME

(71) Applicant: AGENCY FOR SCIENCE, TECHNOLOGY AND RESEARCH, Singapore (SG)

(72) Inventors: Gongyue TANG, Singapore (SG); Kazunori YAMAMOTO, Singapore (SG); Xiaowu ZHANG, Singapore (SG)

(21) Appl. No.: 18/006,921

(22) PCT Filed: Jul. 9, 2021
(86) PCT No.: PCT/SG2021/050406

§ 371 Date: Jan. 26, 2023

(30) Foreign Application Priority Data
Jul. 30, 2020 (SG) 10202007324X

(51) Int. Cl. H01L 25/18; H01L 23/495; H01L 23/367; H01L 23/427; H01L 23/00; H01L 25/00

(52) U.S. Cl. CPC H01L 25/18; H01L 23/3672; H01L 23/427; H01L 23/49537; H01L 24/32; H01L 24/83; H01L 25/50; H01L 2224/32245; H01L 2224/83801

(57) ABSTRACT

Abstract: Various embodiments may relate to a power module package. The power module package may include a power module including a first lead frame, a second lead frame, and at least one chip at least partially between the first lead frame and the second lead frame. The power module package may also include a first heat spreader attached to the first lead frame. The power module package may further include a second heat spreader also attached to the first lead frame such that the first lead frame, the first heat spreader and the second heat spreader form an enclosure defining a cavity containing the at least one chip. The enclosure may include an inlet configured to allow a cooling medium to flow into the cavity and an outlet configured to allow the cooling medium to flow out of the cavity.

### CROSS-REFERENCE TO RELATED APPLICATION

This application claims the benefit of priority of Singapore Application No. 10202007324X filed Jul. 30, 2020, the contents of it being hereby incorporated by reference in its entirety for all purposes.

### TECHNICAL FIELD

Various embodiments of this disclosure may relate to a power module package. Various embodiments of this disclosure may relate to a method of forming a power module package.

### BACKGROUND

The need for high output and high performance power packages has been increased dramatically with the evolution of high power electronics devices for aerospace, automotive, solar panel, wind generation, and power grid applications, in which high power management, switching and conversion are critical. In general, the performance of power package relies on the characteristics of the power semiconductor devices, the packaging technology and the package configuration. Owning to its superior electrical and thermal properties over the conventional silicon based power package, the silicon carbide (SiC) device based power package has attracted extensive interests. On the other side, SiC devices can be much smaller than similarly rated silicon devices.

A SiC based power package can possess very high power dissipation due to its higher power output and greater packaging density, which in turn results in huge challenges in terms of thermal management. Therefore, advanced package design/structures and effective cooling solutions are playing an important role in the development of SiC device based power modules.

Conventional power module- package may include the wire-bond interconnection scheme. Alternatively, double side direct bonded copper (DBC) substrates may be used to form planar interconnection configuration on both sides of the power module. FIG. 1A shows a schematic of a conventional wire-bonded power module. The conventional wire-bonded power module has high package volume due to height of the bond wires, and is only compatible for single side cooling only. FIG. 1B shows a schematic of another conventional single side cooled power module.

As highlighted above, advanced top-of-chip planar interconnection schemes may instead be employed. FIG. 1C shows a schematic of a conventional double side cooled power module package with top and bottom DBC substrates. Commonly, two DBC substrates may be applied on both sides of the power device for power drain, gate and source interconnections, and separate cold plates may be attached to the power module at both sides, thereby forming the double side liquid cooled power module. However, due to the thick/heavy DBC substrates and separate cold plates, the structure of this power module is complex, and the power module is heavy, with large form factor and low cooling efficiency.

In addition, a conventional liquid immersion cooled power module may be formed by assembling the power device with DBC substrates at first, then immersing the assembled power module(s) into an additional liquid immersion bath system. However, the liquid immersion bath system is complex and with low cooling efficiency. FIG. 1D shows schematics of a conventional power module with two DBC substrates and liquid immersion bath systems.

### SUMMARY

Various embodiments may relate to a power module package. The power module package may include a power module including a first lead frame, a second lead frame, and at least one chip at least partially between the first lead frame and the second lead frame. The power module package may also include a first heat spreader attached to the first lead frame. The power module package may further include a second heat spreader also attached to the first lead frame such that the first lead frame, the first heat spreader and the second heat spreader form an enclosure defining a cavity containing the at least one chip. The enclosure may include an inlet configured to allow a cooling medium to flow into the cavity and an outlet configured to allow the cooling medium to flow out of the cavity.

Various embodiments may relate to a method of forming power module package. The method may include forming a power module including a first lead frame, a second lead frame, and at least one chip at least partially between the first lead frame and the second lead frame. The method may also include, forming a first heat spreader attached to the first lead frame. The method may further include forming a second heat spreader also attached to the first lead frame such that the first lead frame, the first heat spreader and the second heat spreader form an enclosure defining a cavity containing the at least one chip. The enclosure may include an inlet configured to allow a cooling medium to flow into the cavity and an outlet configured to allow the cooling medium to flow out of the cavity.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A shows a schematic of a conventional wire-bonded power module.

FIG. 1B shows a schematic of another conventional single side cooled power module.

FIG. 1C shows a schematic of a conventional double side cooled power module package with top and bottom DBC substrates.

FIG. 1D shows schematics of a conventional power module with two DBC substrates and liquid immersion bath systems.

FIG. 2 shows a general illustration of a power module package according to various embodiments.

FIG. 3 shows a general illustration of a method of forming a power module package according to various embodiments.

FIG. 4 is a schematic showing a power module package with device level immersion cooling capability for passive two phase cooling according to various embodiments.

FIG. 5 is a schematic showing a power module package with device level immersion cooling capability for active two phase cooling according to various embodiments.

FIG. 6 is a schematic showing a power module package with device level immersion cooling capability for active single phase cooling according to various embodiments.

FIG. 7 is a schematic showing a power module package according to various embodiments.

FIG. 8A illustrates Steps 1 to 4 of forming the power module package according to various embodiments.

FIG. 8B illustrates Steps 5 to 7 of forming the power module package according to various embodiments.

FIG. 8C illustrates Steps 8 and 9 of forming the power module package according to various embodiments.

FIG. 8D illustrates Step 10 of forming the power module package according to various embodiments.

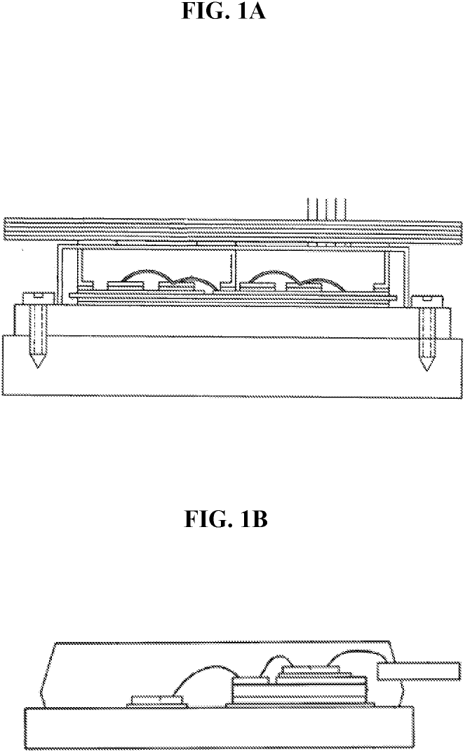

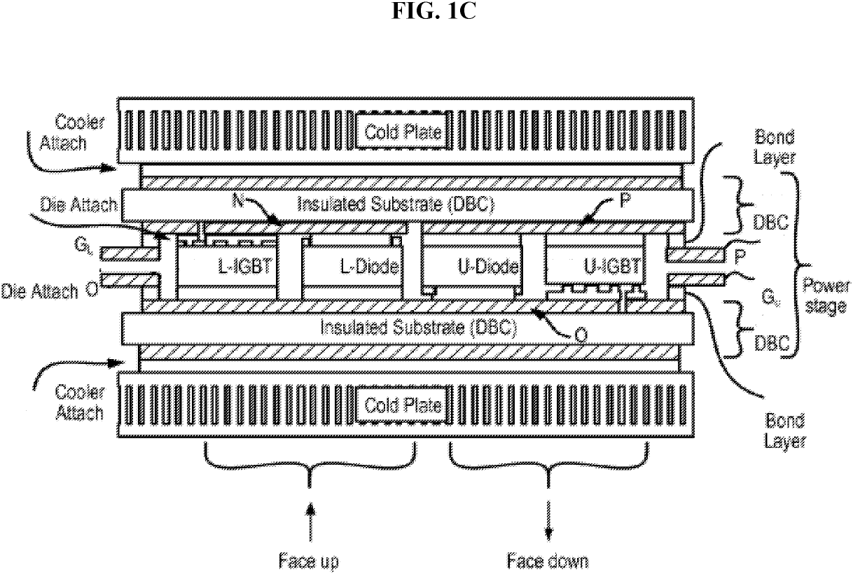

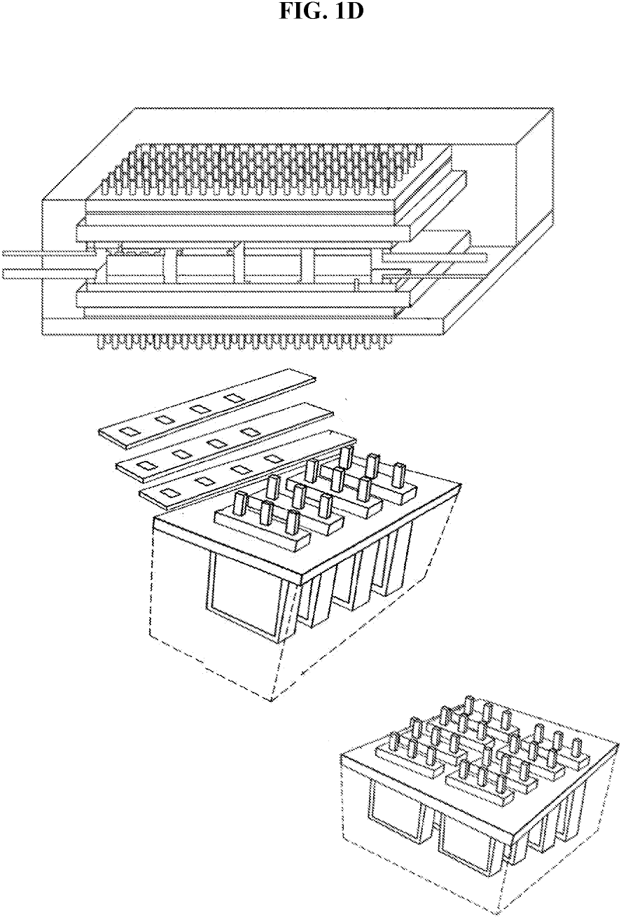

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the packages or methods are analogously valid for the other packages or methods. Similarly, embodiments described in the context of a method are analogously valid for a package, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may seek the address the various issues faced by conventional packages.

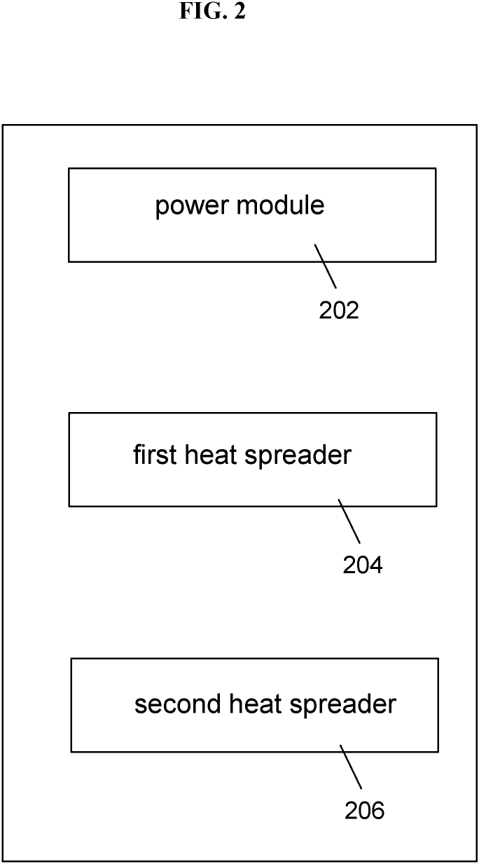

FIG. 2 shows a general illustration of a power module package according to various embodiments. The power module package may include a power module 202 including a first lead frame, a second lead frame, and at least one chip at least partially between the first lead frame and the second lead frame. The power module package may also include a first heat spreader 204 attached to the first lead frame. The power module package may further include a second heat spreader 206 also attached to the first lead frame such that the first lead frame, the first heat spreader and the second heat spreader form an enclosure defining a cavity containing the at least one chip. The enclosure may include an inlet configured to allow a cooling medium to flow into the cavity and an outlet configured to allow the cooling medium to flow out of the cavity.

In other words, the power module package may include a power module 202, a first heat spreader 204, and a second heat spreader 206. The power module may include a first lead frame, a second lead frame, as well as one or more chips between the first lead frame and the second lead frame. The first lead frame, the first heat spreader 204, and the second heat spreader 206 may form an enclosure defining a cavity to contain the one or more chips. In various embodiments, the enclosure may include an inlet and an outlet.

The enclosure may be fully integrated in the power module package. The enclosure and the cavity may be formed during the method of forming the power module package.

In various embodiments, the first lead frame may include one or more fins on a first side. The first lead frame may also include one or more further fins on a second side opposite the first side.

In various embodiments, the one or more fins may be in contact with the first heat spreader 204. The one or more further fins may be in contact with the second heat spreader 206.

In various embodiments, the power module package may be configured such that the cooling medium is in direct contact with the at least one chip. Accordingly, high chip/die level cooling efficiency may be achieved.

The power module may include the cooling medium. In various embodiments, the cooling medium may include a dielectric liquid which is vaporized after absorbing heat generated from the at least one chip. In various embodiments, the vapor of the dielectric liquid may exit the power module package through the outlet. The vapor may then be cooled using an external cooling means or system, and may condense back into the liquid phase. The dielectric liquid (i.e. the liquid phase) may enter the power module package through the inlet. In various other embodiments, the dielectric liquid (i.e. the liquid phase) may exit the outlet and may be cooled using an external cooling means or system. The cooled dielectric liquid may enter the inlet of the power module package.

In various embodiments, the power module package may also include a die attach adhesive layer attaching the at least one chip to the first lead frame.

In various embodiments, the power module package may additionally include a first solder layer bonding the second lead frame to the at least one chip. The power module package may further include a second solder layer bonding the second lead frame to the first lead frame.

In various embodiments, the power module 202 may further include a third lead frame arranged such that the at least one chip is at least partially between the first lead frame and the third lead frame.

In various embodiments, the power module 202 may further include a fourth lead frame, and at least one further chip at least partially between the first lead frame and the fourth lead frame. The at least one further chip may also be contained in the cavity defined by the enclosure.

In various embodiments, the power module 202 may further include a fifth lead frame arranged such that the at least one further chip is at least partially between the first least lead frame and the fifth lead frame.

The first lead frame, the second lead frame, the third lead frame, the fourth lead frame and/or the fifth lead frame may include metals. For instance, in various embodiments, the first lead frame, the second lead frame, the third lead frame, the fourth lead frame and/or the fifth lead frame may include copper and may be copper lead frame(s). In various other embodiments, the first lead frame, the second lead frame, the third lead frame, the fourth lead frame and/or the fifth lead frame may include aluminium or gold. In yet various other embodiments, the first lead frame, the second lead frame, the third lead frame, the fourth lead frame and/or the fifth lead frame may include alloys of copper. In various embodiments, the first heat spreader 204 and/or the second heat spreader 206 may include a material of high thermal conductivity, such as copper or aluminium.

In various embodiments, the lead frames (e.g. copper lead frames) may form lateral and vertical electrical interconnections. The lead frames may provide mechanical support for the chips in the package, enhance heat spreading, and increase surface area for heat exchange between the chips and the cooling medium, thereby improving cooling performance. The lead frames may be formed by a stamping process or an etching process.

In various embodiments, the formation of the enclosure may be fully integrated into the method for forming the power module package. In various embodiments, the enclosure formed within the package may lead to compact size and small form factor.

In various embodiments, the enclosure may include an opening which acts as the inlet, and another opening which acts as the outlet. In various embodiments, the enclosure may include one opening which functions as both the inlet and the outlet.

In various embodiments, the at least one chip may include a silicon carbide (SiC) chip, such as a SiC metal oxide semiconductor field effect transistor (MOSFET) chip. In various embodiments, the at least one further chip may include a silicon carbide (SiC) chip, such as a SiC diode chip. In various other embodiments, the at least one chip and/or the at least one further chip may be any semiconductor chip, such as silicon chip or gallium arsenide chip.

In various embodiments, the power module package may further include a heat sink. The heat sink may be in physical or thermal contact with the second heat spreader 206. The power module package may also include a thermal interface layer in physical contact with the second heat spreader 206. The thermal interface layer may include a thermal interface material (TIM). The heat sink may be in physical contact with the thermal interface layer.

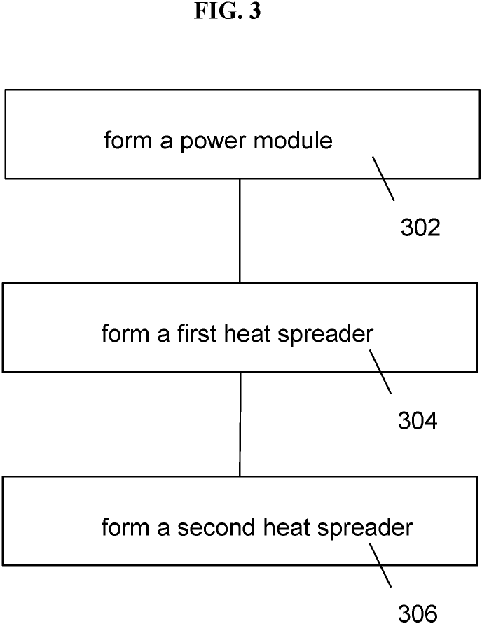

FIG. 3 shows a general illustration of a method of forming a power module package according to various embodiments. The method may include, in 302, forming a power module including a first lead frame, a second lead frame, and at least one chip at least partially between the first lead frame and the second lead frame. The method may also include, in 304, forming a first heat spreader attached to the first lead frame. The method may further include, in 306, forming a second heat spreader also attached to the first lead frame such that the first lead frame, the first heat spreader and the second heat spreader form an enclosure defining a cavity containing the at least one chip. The enclosure may include an inlet configured to allow a cooling medium to flow into the cavity and an outlet configured to allow the cooling medium to flow out of the cavity.

In other words, the method may include forming the power module, the first heat spreader and the second heat spreader. The first lead frame of the power module, the first heat spreader and the second heat spreader may form an enclosure defining a cavity containing the at least one chip.

In various embodiments, the first lead frame may include one or more fins on a first side. The first lead frame may also include one or more further fins on a second side opposite the first side.

In various embodiments, the one or more fins may be in contact with the first heat spreader. The one or more further fins may be in contact with the second heat spreader.

In various embodiments, the power module package may be configured such that the cooling medium is in direct contact with the at least one chip.

In various embodiments, the cooling medium may include a dielectric liquid which is vaporized after absorbing heat generated from the at least one chip.

In various embodiments, the at least one chip may be attached to the first lead frame via a die attach adhesive layer.

In various embodiments, the second lead frame may be bonded to the at least one chip via a first solder layer. The second lead frame may be bonded to the first lead frame via a second solder layer.

In various embodiments, the power module may further include a third lead frame arranged such that the at least one chip is at least partially between the first lead frame and the third lead frame.

In various embodiments, the power module may further include a fourth lead frame, and at least one further chip at least partially between the first lead frame and the fourth lead frame.

In various embodiments, the power module may further include a fifth lead frame arranged such that the at least one further chip is at least partially between the first least lead frame and the fifth lead frame.

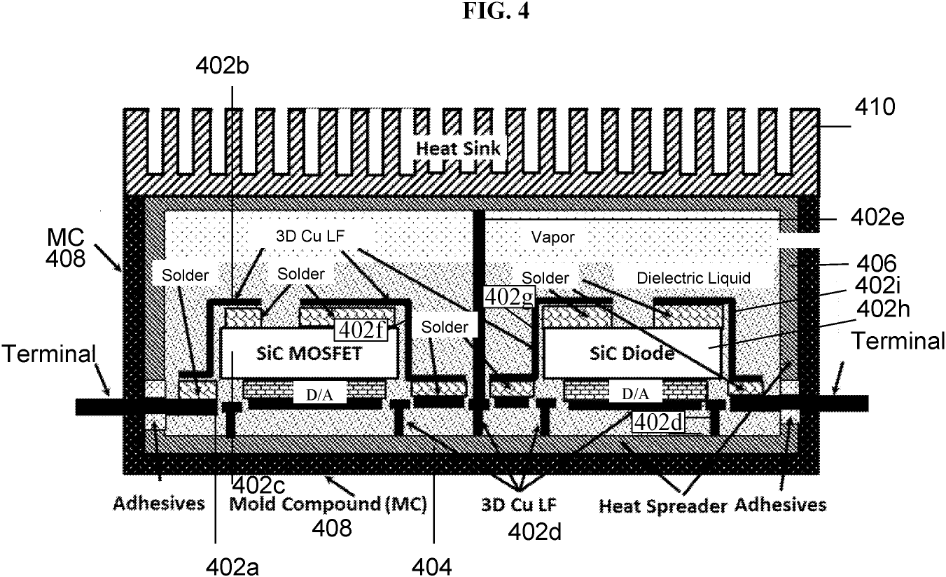

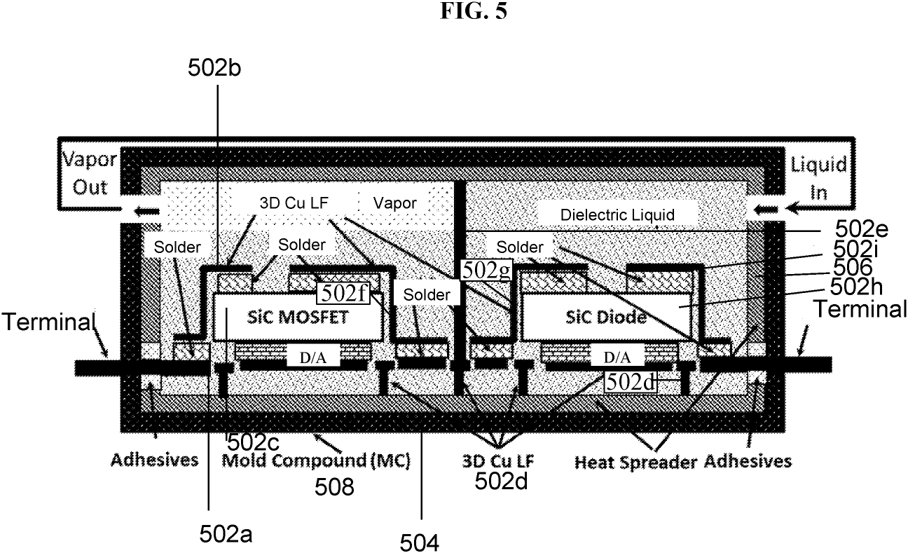

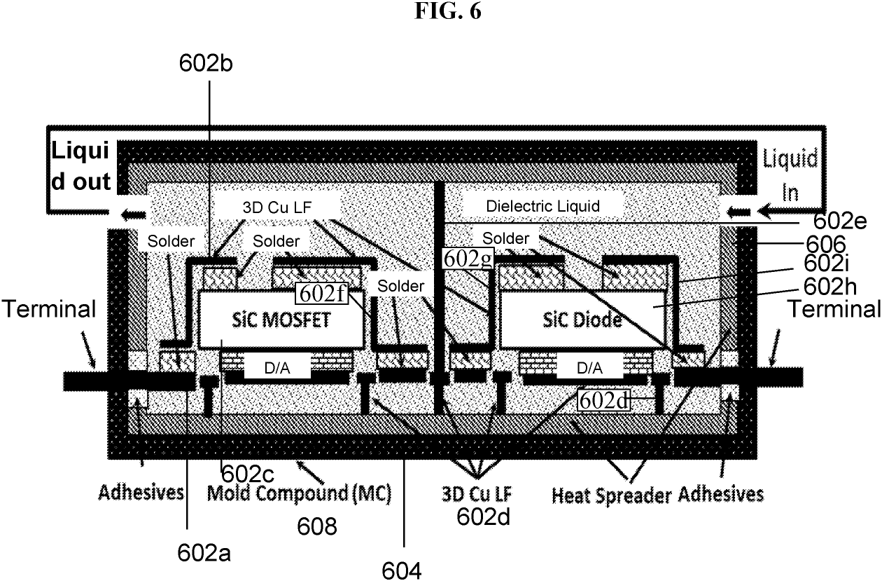

FIG. 4 is a schematic showing a power module package with device level immersion cooling capability for passive two phase cooling according to various embodiments. FIG. 5 is a schematic showing a power module package with device level immersion cooling capability for active two phase cooling according to various embodiments. FIG. 6 is a schematic showing a power module package with device level immersion cooling capability for active single phase cooling according to various embodiments.

In various embodiments, the power module package may include a power module. The power module may include first lead frame 402a, 502a, 602a, a second lead frame 402b, 502b, 602b, and a chip 402c, 502c, 602c (e.g. a SiC MOSFET chip) at least partially between the first lead frame 402a, 502a, 602a and the second lead frame 402b, 502b, 602b. The power module package may also include a first heat spreader 404, 504, 604 attached to the first lead frame 402a, 502a, 602a. The power module package may further include a second heat spreader 406, 506, 606 also attached to the first lead frame 402a, 502a, 602a such that the first lead frame 402a, 502a, 602a, the first heat spreader 404, 504, 604 and the second heat spreader 406, 506, 606 form an enclosure defining a cavity containing the chip 402c, 502c, 602c. The power module package may additionally include adhesive (also referred to adhesive layers or plugs) between the first lead frame 402a, 502a, 602a and the first heat spreader 404, 504, 604, as well as between the first lead frame 402a, 502a, 602a and the second heat spreader 406, 506, 606. The adhesive may hold or attach the heat spreaders 404, 504, 604, 406, 506, 606 to the first lead frame 402a, 502a, 602a, and may also form the enclosure defining the cavity.

The first lead frame 402a, 502a, 602a may include one or more fins 402d, 502d, 602d on a first side; and one or more further fins 402e, 502e, 602e on a second side opposite the first side. In order to avoid clutter and to improve clarity, not all the fins and further fins in FIGS. 4 - 6 have been labelled. The one or more fins 402d, 502d, 602d may be in contact with the first heat spreader 404, 504, 604, while the one or more further fins 402e, 502e, 602e may be in contact with the second heat spreader 406, 506, 606.

The power module may further include a third lead frame 402f, 502f, 602f arranged such that the chip 402c, 502c, 602c is at least partially between the first lead frame 402a, 502a, 602a and the third lead frame 402f, 502f, 602f.

In various embodiments, the power module may further include a fourth lead frame 402g, 502g, 602g, and a further chip 402h, 502h, 602h (e.g. a SiC diode chip) at least partially between the first lead frame 402a, 502a, 602a and the fourth lead frame 402g, 502g, 602g. The power module may further include a fifth lead frame 402i, 502i, 602i arranged such that the further chip 402h, 502h, 602h is at least partially between the first lead frame 402a, 502a, 602a and the fifth lead frame 402i, 502i, 602i.

The lead frames 402a, 502a, 602a, 402b, 502b, 602b, 402f, 502f, 602f, 402g, 502g, 602g, 402i, 502i, 602i may be three dimensional copper lead frames (3D Cu LFs).

The chips 402c, 502c, 602c, 402h, 502h, 602h or semiconductor devices in the power module may be bare dies and/or diodes. By using the die attach (D/A) material and solder materials, these bare dies/diodes 402c, 502c, 602c, 402h, 502h, 602h may be bonded to the lead frames 402a, 502a, 602a, 402b, 502b, 602b, 402f, 502f, 602f, 402g, 502g, 602g, 402i, 502i, 602i at the bottom side (for drain) and top side (for gate and source), forming the lateral and vertical interconnections of the power module. After bonding the dies/diodes 402c, 502c, 602c, 402h, 502h, 602h to the lead frames 402a, 502a, 602a, 402b, 502b, 602b, 402f, 502f, 602f, 402g, 502g, 602g, 402i, 502i, 602i, two heat spreaders 404, 504, 604, 406, 506, 606 (e.g. copper heat spreaders) may be attached to lead frames 402a, 502a, 602a from the bottom and top side. Then, molding process with molding compound (MC) material 408, 508, 608 may be carried out to mold the power module, and the heat spreaders 404, 504, 604, 406, 506, 606. In such a manner, the power module package with device level immersion cooling capability may be assembled. Since the device level immersion cooling solution is fully integrated with power module package, the power module package according to various embodiments may have a smaller form factor, lighter weight, and enhanced cooling efficiency as compared with conventional power module packages.

The power module package shown in FIG. 4 may further include a heat sink 410 for passive cooling. The heat sink 410 may be attached to the second heat spreader 406. The enclosure formed by the first lead frame 402a, the first heat spreader 404, and the second heat spreader 406 may include an opening or openings to allow a cooling medium, e.g. dielectric liquid, to be filled/refilled into the cavity. The power module package shown in FIG. 4 may not require an external cooling loop or an external apparatus.

The power module package shown in FIG. 5 may use active two phase cooling. The enclosure formed by the first lead frame 502a, the first heat spreader 504, and the second heat spreader 506 may include a first opening functioning as an inlet to allow a cooling medium, e.g. dielectric liquid, to flow into the cavity, as well as a second opening functioning as an outlet to allow the vaporized cooling medium, e.g. vapourised dielectric liquid, to flow out of the cavity. The cooling medium may be vapourised after absorbing the heat generated by the chips 502c, 502h. The vaporized cooling medium may be cooled and condensed after flowing out of the outlet, and the cooled and condensed cooling medium (i.e. in the liquid phase) may be reintroduced via the inlet into the cavity. There may be an external pump system to pump the vaporized cooling medium out of the cavity, and the condensed cooling medium into the cavity. There may also be an external condensation system to cool and condense the cooling medium from the vapour phase to the liquid phase.

The power module package shown in FIG. 6 may use active single phase cooling. The enclosure formed by the first lead frame 602a, the first heat spreader 604, and the second heat spreader 606 may include a first opening functioning as an inlet to allow a cooling medium, e.g. dielectric liquid, to flow into the cavity, as well as a second opening functioning as an outlet to allow the heated cooling medium to flow out of the cavity. The cooling medium may be heated after absorbing the heat generated by the chips 602c, 602h. The heated cooling medium may be cooled after flowing out of the outlet, and the cooled cooling medium may be reintroduced via the inlet into the cavity. There may be an external pump system to pump the heated cooling medium out of the cavity, and the cooled cooling medium into the cavity.

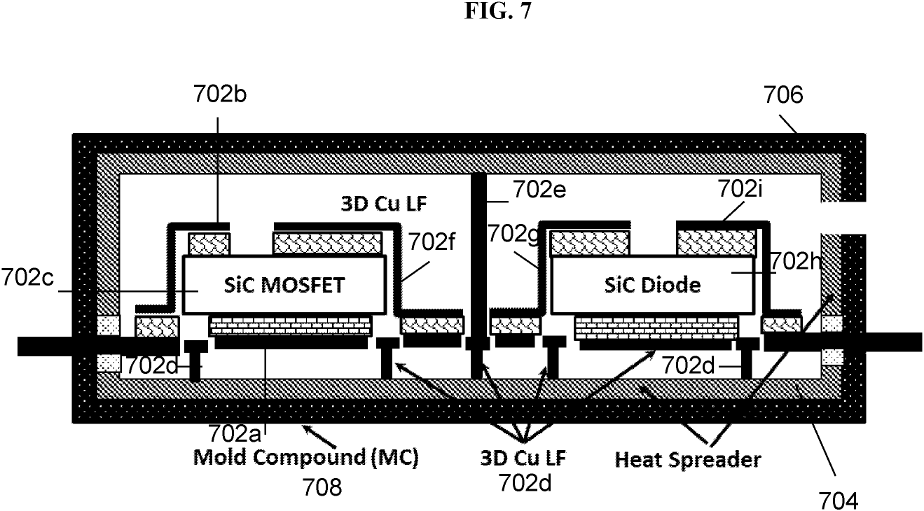

FIG. 7 is a schematic showing a power module package according to various embodiments. Similar to the packages shown in FIGS. 4 - 6, the package shown in FIG. 7 may include lead frames 702a, 702b,702f, 702g, 702i, chips 702c, 702h, heat spreaders 704, 706 and mold compound 708. The first lead frame 702a one or more fins 702d on a first side; and one or more further fins 702e on a second side opposite the first side. The one or more fins 702d may be in contact with the first heat spreader 704, while the one or more further fins 702e may be in contact with the second heat spreader 706. The fins 702d, 702e may not only form the interconnections of the power module, but may also provide the support to the chips 702c, 702h, but may also enhance the heat spreading of the chips 702c, 702h, and increase the surface area for heat transfer between the chips 702c, 702h and the cooling medium. The package shown in FIG. 7 may be similar to the package shown in FIG. 4. FIG. 7 highlights the lead frames and heat spreaders shown in the package of FIG. 4.

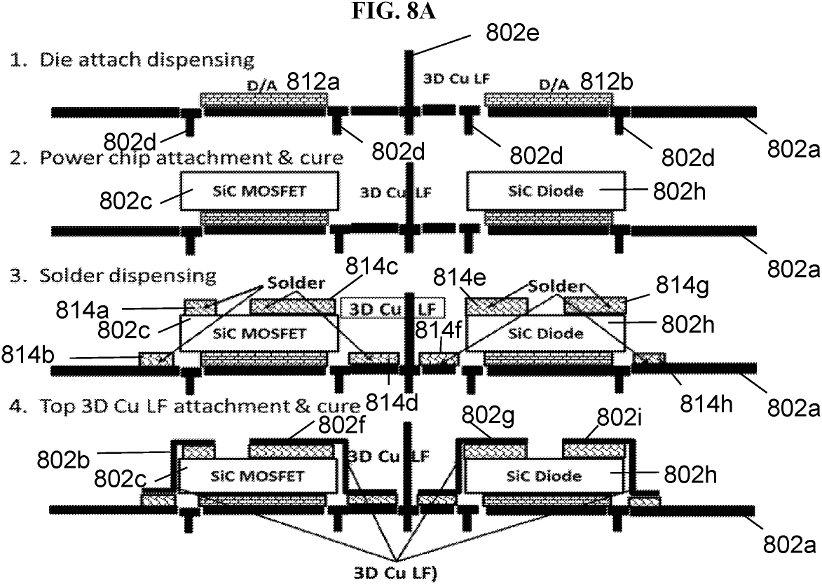

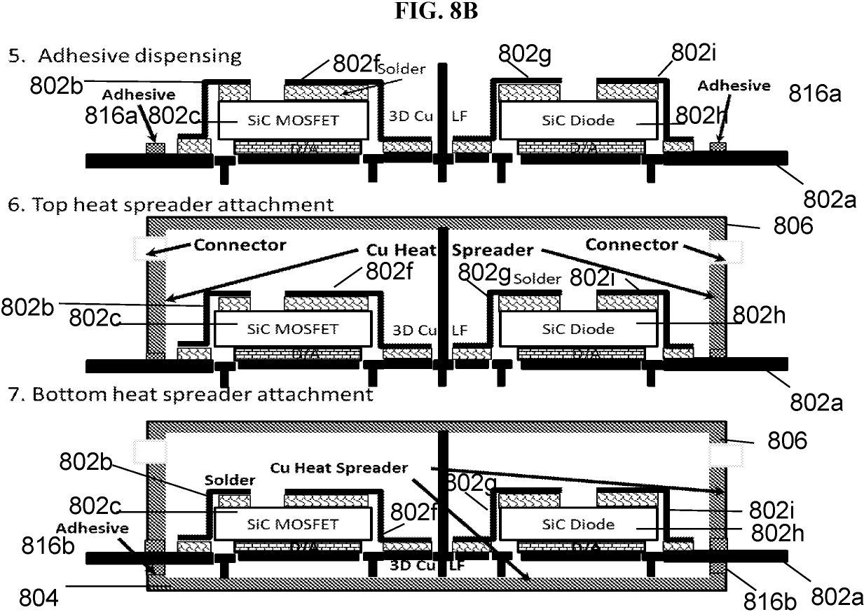

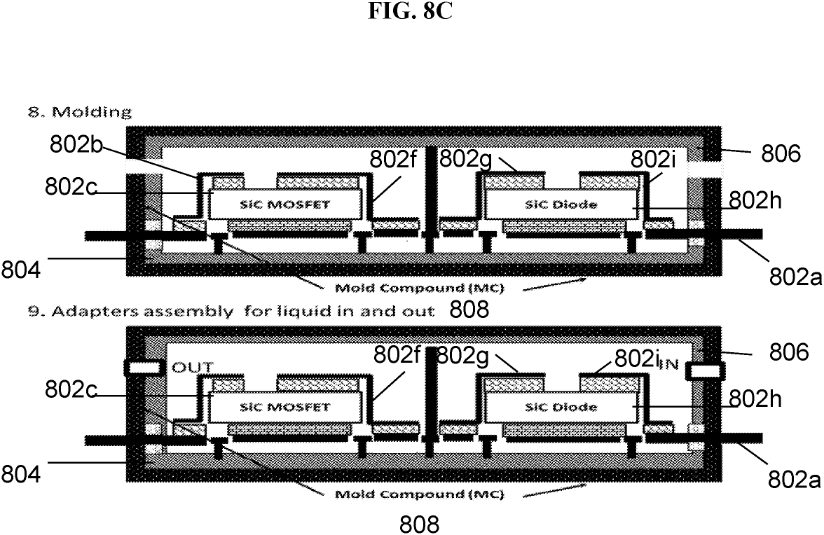

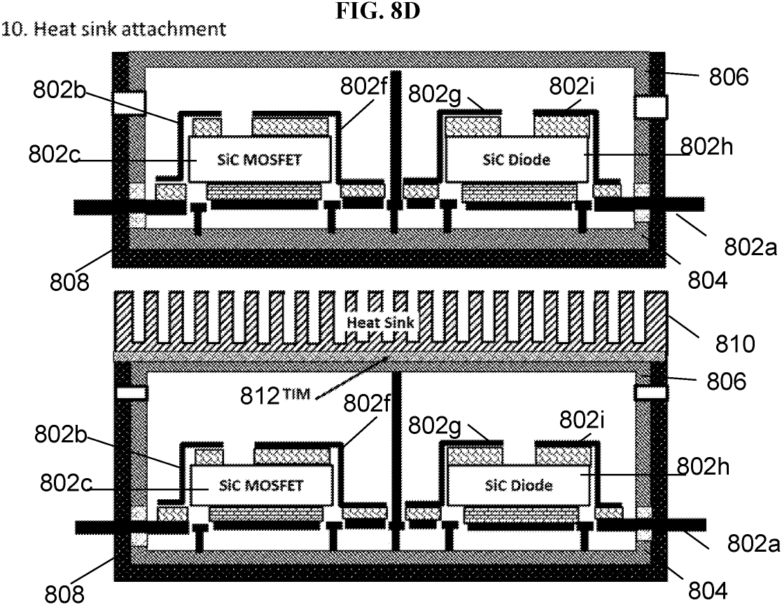

FIGS. 8A - D illustrate a method of forming the power module package according to various embodiments. FIG. 8A illustrates Steps 1 to 4 of forming the power module package according to various embodiments. In Step 1, die attach (D/A) material may be dispensed onto a first lead frame 802a to form die attach adhesive layers 812a, 812b. The first lead frame 802a may include one or more fins 802d on a first side; and one or more further fins 802e on a second side opposite the first side. In order to avoid clutter and improve clarity, the die attach adhesive layers 812a, 812b and the fins 802d, 802e are not labelled in the subsequent steps.

In Step 2, the chip 802c (e.g. a SiC MOSFET chip) may be attached to the die attach adhesive layer 812a, while the further chip 802h (e.g. a SiC diode chip) may be attached to the die attach adhesive layer 812b. The die attach adhesive layers 812a, 812b may then be cured,

In Step 3, solder may be dispensed to form solder layers 814a-h. In order to avoid clutter and improve clarity, the solder layers 814a-h are not labelled in the subsequent steps.

In Step 4, the top lead frames i.e. the second lead frame 802b, the third lead frame 802f, the fourth lead frame 802g and the fifth lead frame 802i may be attached. The second lead frame 802b may be attached to the first solder layer 814a and to the second solder layer 814b. The first solder layer 814a may bond the second lead frame 802b to the chip 802c, while the second solder layer 814b may bond the second lead frame 802b to the first lead frame 802a. The third lead frame 802f may be attached to the third solder layer 814c and the fourth solder layer 814d. The third solder layer 814c may bond the third lead frame 802f to the chip 802c, while the fourth solder layer 814d may bond the third lead frame 802f to the first lead frame 802a.

Likewise, the fourth lead frame 802g may be attached to the fifth solder layer 814e and the sixth solder layer 814f. The fifth solder layer 814e may bond the fourth lead frame 802g to the further chip 802h, while the sixth solder layer 814f may bond the fourth lead frame 802g to the first lead frame 802a. The fifth lead frame 802i may be attached to the seventh solder layer 814g and the eighth solder layer 814h. The seventh solder layer 814g may bond the fifth lead frame 802i to the further chip 802h, while the eighth solder layer 814h may the fifth lead frame 802i to the first lead frame 802a. The solder layers 814a-h may then be cured.

FIG. 8B illustrates Steps 5 to 7 of forming the power module package according to various embodiments. Step 5 of FIG. 8B may follow from Step 4 of FIG. 8A. In Step 5, adhesive may be dispensed onto a top surface of the first lead frame 802a to form adhesive layers 816a.

In Step 6, the top heat spreader 806 may be attached to the adhesive layers 816a. The top heat spreader 806 may come into physical and/or thermal contact with the one or more further fins 802e. The top heat spreader 806 may include a connector or hole which subsequently functions as an inlet, and another connector or hole which subsequently functions as an outlet.

In Step 7, adhesive may be dispensed onto a bottom surface of the first lead frame 802a to form adhesive layers 816b. The bottom heat spreader 804 may be attached to the adhesive layers 816b. The bottom heat spreader 804 may come into physical and/or thermal contact with the one or more fins 802d. While FIG. 8B shows the top heat spreader 806 being attached to the first lead frame 802a first, followed by the bottom heat spreader 804, in various other embodiments, the bottom heat spreader 804 may be attached to the first lead frame 802a first, followed by the top heat spreader 806.

FIG. 8C illustrates Steps 8 and 9 of forming the power module package according to various embodiments. Step 8 of FIG. 8C may follow from Step 7 of FIG. 8B. In Step 8, molding with molding compound (MC) material 808 may be carried out. The mold compound material 808 may cover the outer surfaces of the heat spreaders 804, 806. The heat spreaders 804, 806 and the power module (excluding the inlet and the outlet) may be encapsulated by the molding compound (MC) material 808. Curing of the mold compound material 808 may be carried out.

Step 9 may be carried out for power module packages configured for active cooling. Adaptor assembly process may be carried out to configure one connector or opening so that it functions as an inlet, and to configure another connector or opening so that it functions as an outlet.

FIG. 8D illustrates Step 10 of forming the power module package according to various embodiments. Step 10 of FIG. 8D may follow from Step 9 of FIG. 8C. Step 10 may be used to form a power module package with passive cooling capability. The top heat spreader 806 may be exposed by using the back grinding process. The back grinding process may remove the mold compound 808 on the top surface of the top heat spreader 806. Thermal interface material (TIM) may be deposited to form a thermal interface layer 812. A heat sink 810 may be attached to the thermal interface layer 812.

Various embodiments may include an enclosure formed by three dimensional copper lead frames (3D Cu LFs), heat spreaders and molding compound.

Various embodiments may relate to a device level immersion cooling structure fully integrated into the power module package, achieving passive, device level immersion and two phase cooling capability.

Various embodiments may relate to a device level immersion cooling structure fully integrated with the power module, achieving active, device level immersion and two phase cooling capability.

Various embodiments may relate to a device level immersion cooling structure fully integrated into the power module, achieving active, device level immersion and single phase cooling capability.

Various embodiments may include specially designed 3D Cu LFs, which have at least one fin at each side (the bottom and top side), which form the interconnections support for the SiC chips or devices in the package, enhance the heat spreading and increase the surface area for heat exchange between the chips and the cooling medium.

Various embodiments may relate to power module packages with device level immersion, passive or active, single or two phase cooling capability. This may be achieved by fully integrating the cooling structure (i.e. an enclosure formed by the 3D Cu lead frame, Cu heat spreaders and molding compound) into the power module package. Various embodiments may be able to provide the high cooling efficiency by fully integrating the device level immersion cooling technology into the power module. In addition, the specially designed 3D Cu LFs with fins may not only form the interconnections of the power module, but may also provide support to the SiC devices, enhance the heat spreading of the devices and increase the surface area for heat exchange between the devices and the cooling medium.

Various embodiments may be used, for instance, in inverters of automotive power trains, in power inverter units in generators (green and renewable energy industry), in aerospace/marine/train high power inverter modules, and in industrial equipment high power inverter modules.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non- limiting examples. In addition, where features or aspects of the invention are described in terms of Markush groups, those skilled in the art will recognize that the invention is also thereby described in terms of any individual member or subgroup of members of the Markush group.

1. A power module package comprising:
a power module comprising a first lead frame, a second lead frame, and at least one chip at least partially between the first lead frame and the second lead frame;
a first heat spreader attached to the first lead frame; and
a second heat spreader also attached to the first lead frame such that the first lead frame, the first heat spreader and the second heat spreader form an enclosure defining a cavity containing the at least one chip;
wherein the enclosure comprises an inlet configured to allow a cooling medium to flow into the cavity and an outlet configured to allow the cooling medium to flow out of the cavity.

2. The power module package according to claim 1,
wherein the first lead frame comprises one or more fins on a first side; and one
or more further fins on a second side opposite the first side.

3. The power module package according to claim 2,
wherein the one or more fins are in contact with the first heat spreader; and
wherein the one or more further fins are in contact with the second heat spreader.

4. The power module package according to claim 1, wherein the power module package is configured such that the cooling medium is in direct contact with the at least one chip.

5. The power module package according to claim 1,
wherein the cooling medium comprises a dielectric liquid which is vaporized after absorbing heat generated from the at least one chip.

6. The power module package according to claim 1, further comprising:
a die attach adhesive layer attaching the at least one chip to the first lead frame.

7. The power module package according to claim 1, further comprising:
a first solder layer bonding the second lead frame to the at least one chip; and
a second solder layer bonding the second lead frame to the first lead frame.

8. The power module package according to claim 1,
wherein the power module further comprises a third lead frame arranged such that the at least one chip is at least partially between the first lead frame and the third lead frame.

9. The power module package according to claim 8,
wherein the power module further comprises a fourth lead frame, and at least one further chip at least partially between the first lead frame and the fourth lead frame.

10. The power module package according to claim 9, wherein the power module further comprises a fifth lead frame arranged such that the at least one further chip is at least partially between the first lead frame and the fifth lead frame.

11. A method of forming a power module package, the method comprising:
forming a power module comprising a first lead frame, a second lead frame, and at least one chip at least partially between the first lead frame and the second lead frame;
forming a first heat spreader attached to the first lead frame; and
forming a second heat spreader also attached to the first lead frame such that the first lead frame, the first heat spreader and the second heat spreader form an enclosure defining a cavity containing the at least one chip;
wherein the enclosure comprises an inlet configured to allow a cooling medium to flow into the cavity and an outlet configured to allow the cooling medium to flow out of the cavity.

12. The method according to claim 11,
wherein the first lead frame comprises one or more fins on a first side; and one
or more further fins on a second side opposite the first side.

13. The method according to claim 12,
wherein the one or more fins are in contact with the first heat spreader; and
wherein the one or more further fins are in contact with the second heat spreader.

14. The method according to claim 11,
wherein the power module package is configured such that the cooling medium is in direct contact with the at least one chip.

15. The method according to claim 11,
wherein the cooling medium comprises a dielectric liquid which is vaporized after absorbing heat generated from the at least one chip.

16. The method according to claim 11,
wherein the at least one chip is attached to the first lead frame via a die attach adhesive layer.

17. The method according to claim 11,
wherein the second lead frame is bonded to the at least one chip via a first solder layer; and
wherein the second lead frame is bonded to the first lead frame via a second solder layer.

18. The method according to claim 1,
wherein the power module further comprises a third lead frame arranged such that the at least one chip is at least partially between the first lead frame and the third lead frame.

19. The method according to claim 18,
wherein the power module further comprises a fourth lead frame, and at least one further chip at least partially between the first lead frame and the fourth lead frame.

20. The method according to claim 19,
wherein the power module further comprises a fifth lead frame arranged such that the at least one further chip is at least partially between the first least lead frame and the fifth lead frame.
